(19) United States
(12) Patent Application Publication
(10) Pub. No.: US 2010/0226102 A1
(43) Pub. Date: Sep. 9, 2010

(54) PRINTED CIRCUIT BOARD UNIT

(75) Inventors: Tsuyoshi SO, Kawasaki (JP); Hideo Kubo, Kawasaki (JP); Misao Umematsu, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/706,962

(22) Filed: Feb. 17, 2010

(30) Foreign Application Priority Data
Mar. 3, 2009 (JP) 2009-49625

(51) Int. Cl. H05K 1/00

(52) U.S. Cl. 361/748

(57) ABSTRACT

A printed circuit board unit includes a printed wiring board, an electronic component package mounted on a front surface of the printed wiring board, a radiating plate that is placed on an upper surface of the electronic component package, a bolt that has a head and a tip protruding from a back surface of the printed wiring board, and penetrates through the radiating plate and the printed wiring board, a reinforcing plate separated from the back surface of the printed wiring board by a predetermined gap, a stud arranged on a front surface of the reinforcing plate and coupled with the tip of the bolt, and a shock absorbing plate that is arranged between the reinforcing plate and the back surface of the printed wiring board.

### CROSS-REFERENCE TO RELATED APPLICATION

This application is based upon and claims priority to prior Japanese Patent Application No. 2009-49625 filed on Mar. 3, 2009 in the Japan Patent Office, the entire contents of which are incorporated herein by reference.

### FIELD

Various embodiments described herein relate to a printed circuit board unit.

### BACKGROUND

In a printed circuit board unit, such as a motherboard, a heat sink is placed on an upper surface of an electronic component package which is mounted on the front surface of a printed wiring board. The heat sink is coupled to the printed wiring board by bolts. The bolts penetrate through a radiating plate of the heat sink and the printed wiring board. The bolts are screwed into studs at the back side of the printed wiring board. The studs are fixed onto a sheet metal extending in parallel to the back surface of the printed wiring board with a predetermined gap interposed between the sheet metal and the printed wiring board. Also, helical springs are respectively arranged between heads of the bolts and the front surface of the radiating plate. The helical springs exert elastic forces that cause the heads of the bolts to move away from the front surface of the radiating plate. Consequently, the heat sink is pressed toward the electronic component package.

[PATENT DOCUMENT 1] Japanese Laid-open Patent Publication No. 8-247117

[PATENT DOCUMENT 2] Japanese Laid-open Patent Publication No. 2002-164680

[PATENT DOCUMENT 3] Japanese Laid-open Patent Publication No. 2000-332168

### SUMMARY

A printed circuit board unit includes a printed wiring board, an electronic component package mounted on a front surface of the printed wiring board, a radiating plate that is placed on an upper surface of the electronic component package, a bolt that has a head and a tip protruding from a back surface of the printed wiring board, and penetrates through the radiating plate and the printed wiring board, a reinforcing plate separated from the back surface of the printed wiring board by a predetermined gap, a stud arranged on a front surface of the reinforcing plate and coupled with the tip of the bolt, and a shock absorbing plate that is arranged between the reinforcing plate and the back surface of the printed wiring board.

### BRIEF DESCRIPTION OF THE DRAWINGS

FIG. 1 is a perspective view schematically depicting the external appearance of an information processing apparatus, as an example of an electronic apparatus;

FIG. 2 is a perspective view schematically depicting the external appearance of a printed circuit board unit according to a first embodiment;

FIG. 3 is a cross-sectional view of the printed circuit board unit taken along line 3-3 in FIG. 2;

FIG. 4 is a partly exploded perspective view schematically depicting the structure of the printed circuit board unit according to the first embodiment;

FIG. 5 is a cross-sectional view schematically depicting the structure of a printed circuit board unit according to a second embodiment;

FIG. 6 is a partly exploded perspective view schematically depicting the structure of the printed circuit board unit according to the second embodiment;

FIG. 7 is a cross-sectional view schematically depicting the structure of a printed circuit board unit according to a third embodiment; and

FIG. 8 is a partly exploded perspective view schematically depicting the structure of the printed circuit board unit according to the third embodiment.

### DESCRIPTION OF EMBODIMENTS

Embodiments will be described below with reference to the drawings.

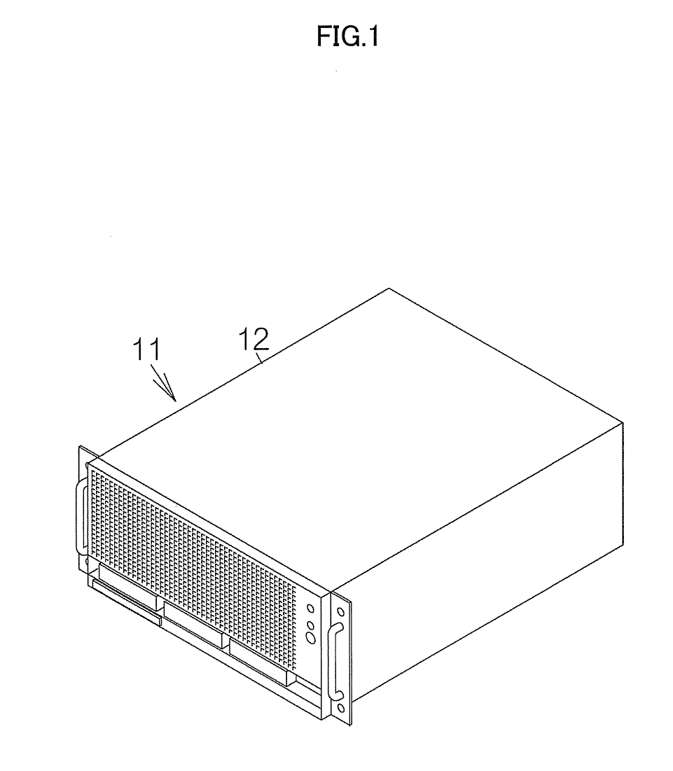

FIG. 1 schematically depicts the external appearance of an information processing apparatus 11, as an example of an electronic apparatus. The information processing apparatus 11 includes a casing 12. The casing 12 has an accommodation space. A motherboard is arranged in the accommodation space. For example, a semiconductor component such as an electronic component package and a main memory are mounted on the motherboard. The electronic component executes various data processing operations, in accordance with a software program and data which are held in a main memory. The software program and data may be stored in a mass storage such as a hard disk drive (HDD) that is also arranged in the accommodation space. Such an information processing apparatus 11 is, for example, mounted on a rack.

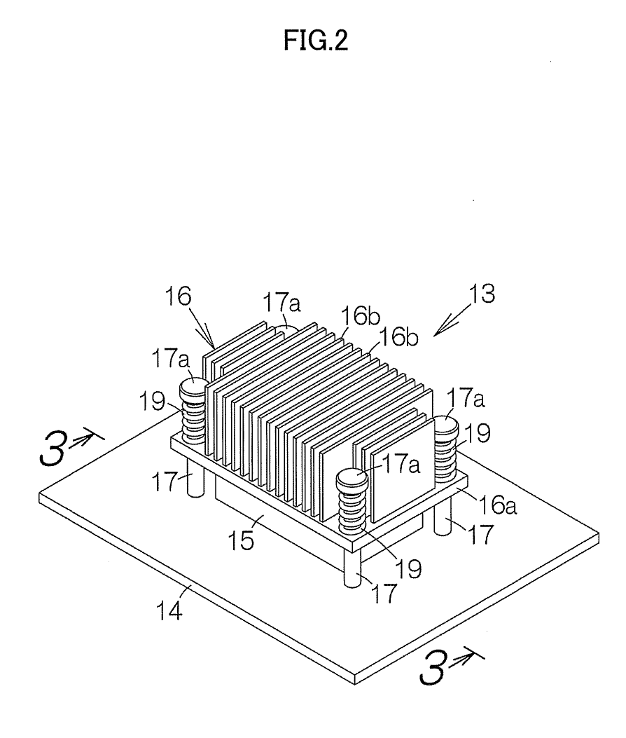

FIG. 2 schematically depicts the external appearance of the printed circuit board unit, i.e., a motherboard 13 according to a first embodiment. The motherboard 13 includes a large printed wiring board 14. The printed wiring board 14 uses, for example, a resin substrate. An electronic component package, e.g., a Large Scale Integrated circuit chip package 15 (hereinafter, referred to as LSI chip package 15) is mounted on the front surface of the printed wiring board 14. The LSI chip package 15 will be described later in detail.

A heat sink 16 as an example of a radiating member is mounted on an upper surface of the LSI chip package 15. The heat sink 16 includes a radiating plate 16a extending in parallel to the front surface of the printed wiring board 14. The radiating plate 16a has a profile that extends outward as compared with the profile of the LSI chip package 15. A flat lower surface of the radiating plate 16a faces the upper surface of the LSI chip package 15. A plurality of fins 16b are fixed to the radiating plate 16a. The respective fins 16b are vertically arranged on an upper surface of the radiating plate 16a. The fins 16b are arrayed in parallel to one another. Air flow paths are provided between the adjacent fins 16b. The air flow paths extend in a common direction. The radiating plate 16a and the fins 16b may be formed of a metal material, such as aluminum or copper, for example.

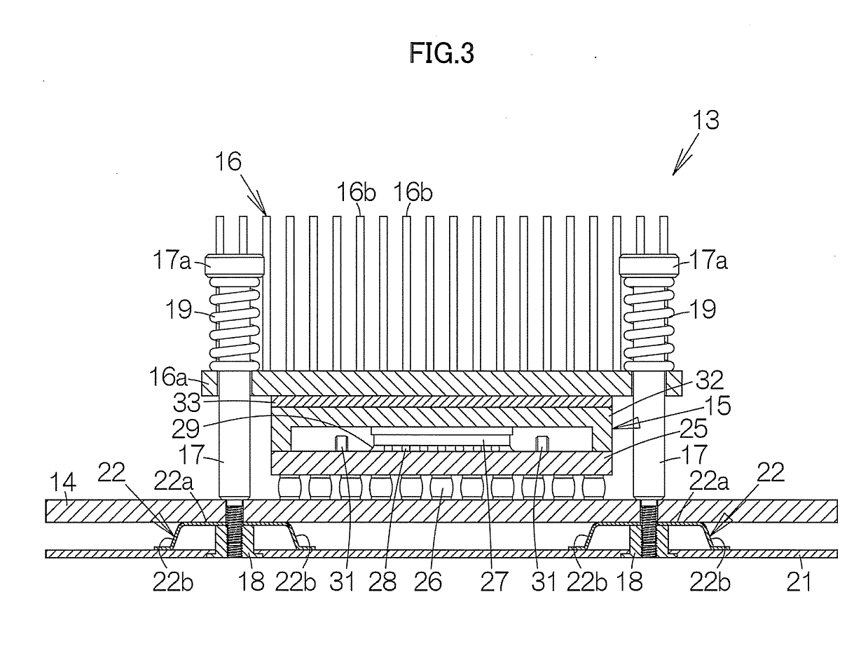

The heat sink 16 is coupled to the printed wiring board 14. For example, four bolts 17 are used for coupling the heat sink 16 to the wiring board 14. The bolts 17 are arranged outside the four corners of the LSI chip package 15 at positions on the extensions of the diagonals of the LSI chip package 15. The bolts 17 penetrate through the radiating plate 16a and the printed wiring board 14. Also referring to FIG. 3, tips of the bolts 17 protrude from the back surface of the printed wiring board 14. The tips of the bolts 17 are coupled to the studs 18 at the back side of the printed wiring board 14. Helical springs 19 as an example of elastic members are respectively arranged between heads 17a of the bolts 17, namely flanges, and the radiating plate 16a. The helical springs 19 exert elastic forces that cause the heads 17a of the bolts 17 to move away from the radiating plate 16a. Consequently, the radiating plate 16a is pressed toward the LSI chip package 15.

A reinforcing board 21 is arranged at the back side of the printed wiring board 14. The reinforcing board 21 extends in parallel to the back surface of the printed wiring board 14. The reinforcing plate 21 is separated from the back surface of the printed wiring board 14 by a predetermined gap. The studs 18 are coupled to the reinforcing plate 21 at positions corresponding to the bolts 17. The studs 18 are vertically arranged on the front surface of the reinforcing plate 21. The reinforcing plate 21 is formed of a sheet metal such as a stainless steel sheet, for example. The studs 18 are formed of internally threaded studs. The studs 18 are fixed to the reinforcing plate 21 by press fitting, for example. The internal threads are formed in the studs 18. External threads at the tips of the bolts 17 respectively mesh with the internal threads in the studs 18. Shock absorbing plates 22 are arranged between upper ends of the studs 18 and the back surface of the printed wiring board 14. The shock absorbing plates 22 are respectively provided for the studs 18.

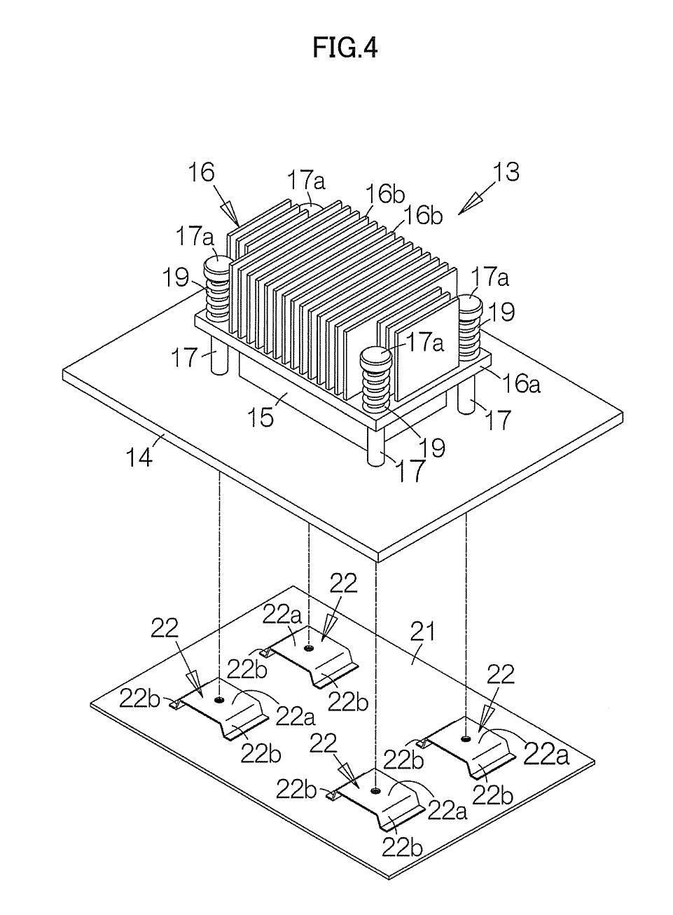

Also referring to FIG. 4, each shock absorbing plate 22 includes a contact plate 22a that contacts the back surface of the printed wiring board 14, and a pair of attachment plates 22b that are bent from both ends of the contact plate 22a and are mounted on the front surface of the reinforcing plate 21. The shock absorbing plate 22 is formed of a sheet metal such as a stainless steel sheet, for example. The front surface of the contact plate 22a has a larger area than an area of an upper end surface of each stud 18. The contact plate 22a extends along the back surface of the printed wiring board 14. Thus, the front surface of the contact plate 22a supports the back surface of the printed wiring board 14. Consequently, the contact plate 22a contacts the back surface of the printed wiring board 14 by a predetermined contact area. Meanwhile, the shock absorbing plate 22 is joined to the reinforcing plate 21 by the attachment plates 22b. For the joining of the shock absorbing plate 22 by the attachment plates 22b, rivets (not depicted) may be used, for example.

Referring to FIG. 3, the LSI chip package 15 includes a package board 25. The package board 25 uses a ceramic substrate, for example. The package board 25 has a polygonal profile. A plurality of terminal bumps 26, i.e., balls of a BGA (Ball Grid Array) package are arranged on the front surface of the printed wiring board 14 within the profile of the package board 25. The terminal bumps 26 are formed of a solder material. For example, the solder material may use lead-free solder. The lead-free solder may be constituted by an alloy using tin, silver, and copper, for example.

The package board 25 is placed on upper surfaces of the terminal bumps 26. Thus, the package board 25 is joined to the front surface of the printed wiring board 14 through the terminal bumps 26. The terminal bumps 26 define a terminal bump group. An electronic component, i.e., a LSI chip 27 is mounted on the front surface of the package board 25. The LSI chip 27 has a square profile, for example. Terminal bumps 28 are arrayed in a matrix form on the front surface of the package board 25. The LSI chip 27 is placed on upper surfaces of the terminal bumps 28.

A plurality of input/output signal lines are formed in the LSI chip 27. The input/output signal lines are respectively connected with the terminal bumps 28. Thus, the input/output signal lines are drawn from the LSI chip 27. The terminal bumps 28 are sealed on the package board 25. That is, the space between the LSI chip 27 and the package board 25 is filled with a resin material 29. In addition, electronic components 31 such as a chip capacitor or a chip resistor may be mounted on the package board 25.

A thermal conduction member, e.g., a heat spreader 32 is placed on the front surface of the package board 25. The heat spreader 32 is brazed to the front surface of the package board 25 by using a solder material, for example. The heat spreader 32 is formed of a metal material such as copper, for example. The heat spreader 32 contacts the front surface of the LSI chip 27. The front surface of the LSI chip 27 is brazed to a lower surface of the heat spreader 32 by using a solder material, for example. Thus, thermal energy of the LSI chip 27 is efficiently transferred to the heat spreader 32. The radiating plate 16a is placed on an upper surface of the heat spreader 32. For example, a heat transfer sheet 33 is arranged between the radiating plate 16a and the heat spreader 32. The thermal energy is transferred from the heat spreader 32 to the heat sink 16. The thermal energy is radiated to the outside air from the heat sink 16.

For example, when the motherboard 13 is carried, or the motherboard 13 is assembled into the information processing apparatus 11, if an external force acts on the printed wiring board 14, a stress may be generated in the printed wiring board 14. As described above, each contact plate 22a of the shock absorbing plate 22 contacts the back surface of the printed wiring board 14. The contact area is larger than a case in which the upper end of each stud 18 contacts the back surface of the printed wiring board 14, and hence, the stress can be properly dispersed in the printed wiring board 14. Accordingly, cracking of the printed wiring board 14, and breaking of the wiring pattern in the printed wiring board 14 can be prevented. Also, the reinforcing plate 21 and the shock absorbing plate 22 are formed of a relatively thin sheet metal. Thus, the motherboard 13 can be reduced in its total weight.

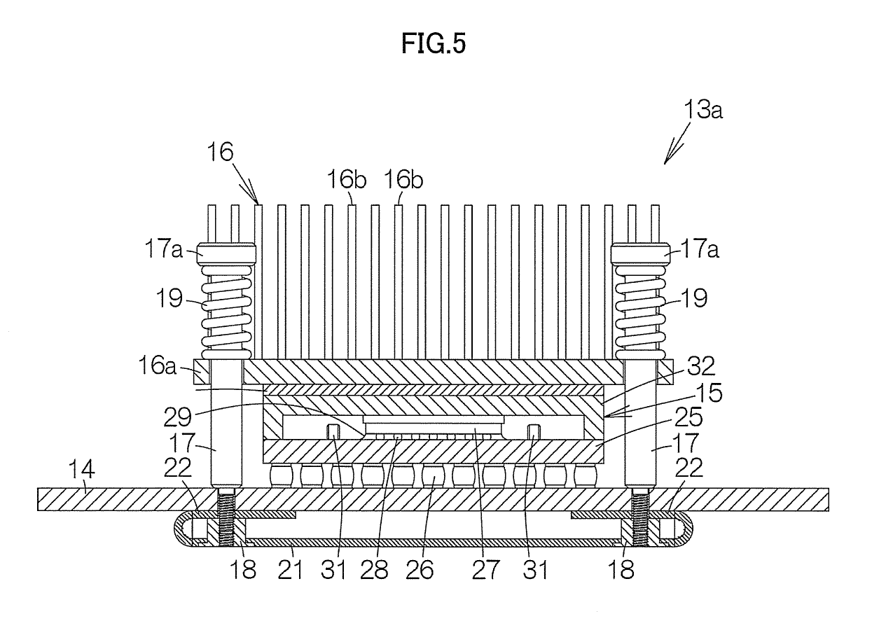

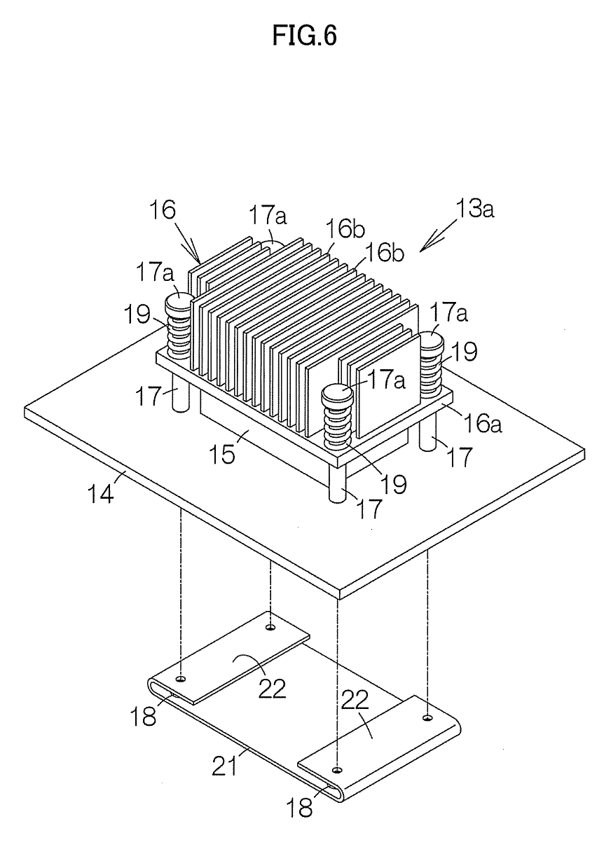

FIG. 5 schematically depicts the structure of a motherboard 13a according to a second embodiment. In the motherboard 13a, a shock absorbing plate 22 is integrated with a reinforcing plate 21. Also referring to FIG. 6, a pair of shock absorbing plates 22 are integrated with the reinforcing plate 21. The reinforcing plate 21 and the shock absorbing plates 22 may be formed of a sheet metal such as a stainless steel sheet, for example, by “hat bending” method. Each shock absorbing plate 22 is arranged between a pair of studs 18 and a printed wiring board 14. The same reference numerals are applied to configurations and structures that are equivalent to those described above. With the motherboard 13a, advantages similar to the first embodiment described above can be attained. Also, since the shock absorbing plate 22 is arranged between the pair of studs 18 and the back surface of the printed wiring board 14, the shock absorbing plate 22 can contact the back surface of the printed wiring board 14 by a larger contact area than that described above. The stress can be further properly dispersed.

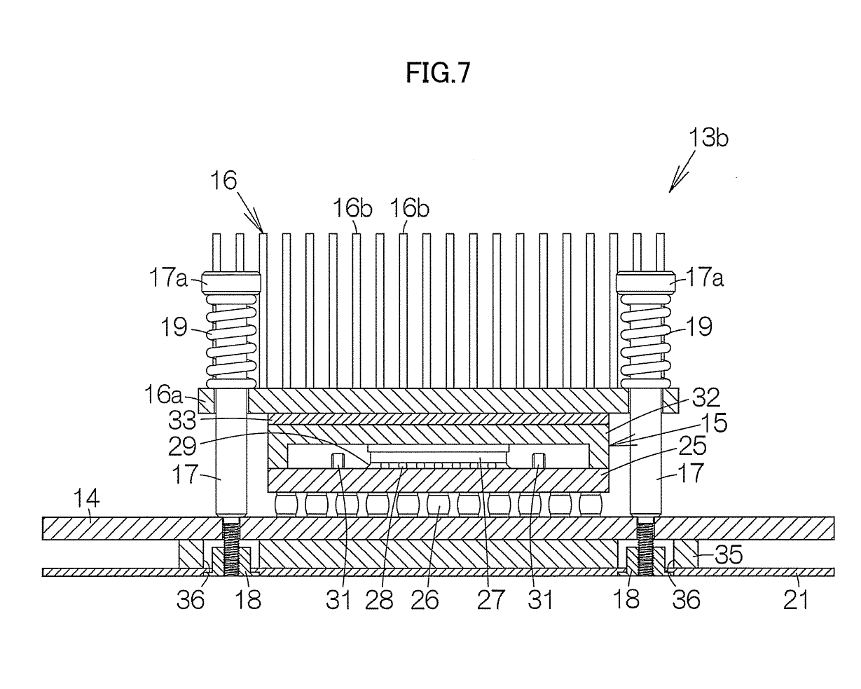

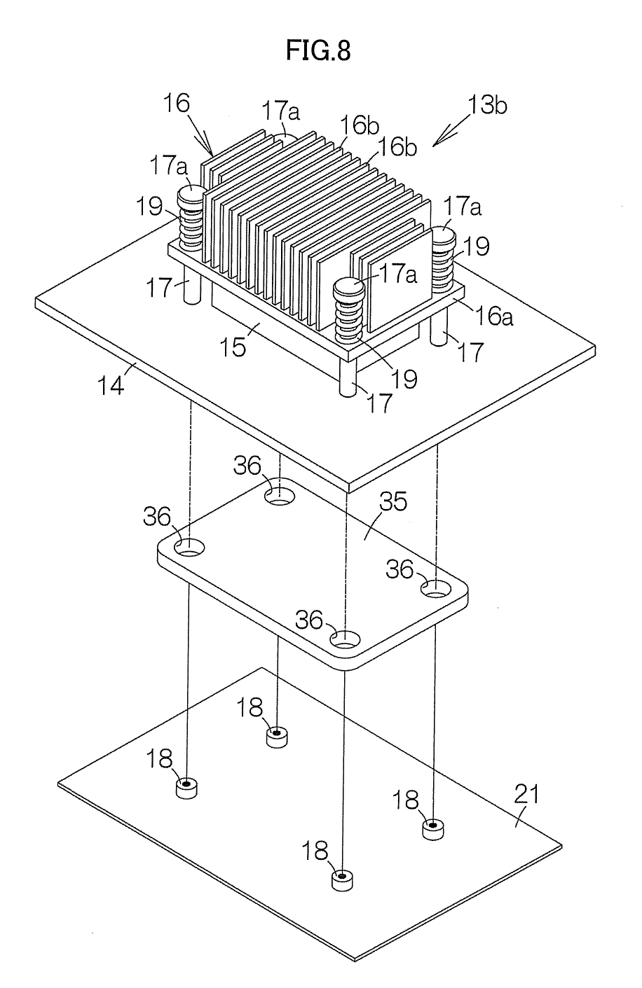

FIG. 7 schematically depicts the structure of a motherboard 13b according to a third embodiment. In the motherboard 13b, a flat-plate-like spacer 35 is arranged between the front surface of a reinforcing plate 21 and the back surface of a printed wiring board 14. The spacer 35 is formed of a metal material, such as an aluminum alloy or stainless steel, for examples. The reinforcing plate 21 has studs 18 that are attached to through holes 36. The through holes 36 penetrate from the front surface to the back surface of the spacer 35. The height of each stud 18 from the front surface of the reinforcing plate 21 to an upper end of the stud 18 is smaller than the thickness of the spacer 35. Consequently, a predetermined gap is provided between the upper end of the stud 18 and the back surface of the printed wiring board 14. Also referring to FIG. 8, the through holes 36 are respectively formed for the studs 18. The spacer 35 contacts the back surface of the printed wiring board 14 at positions outside the through holes 36 by a large contact area. The same reference numerals are applied to configurations and structures that are equivalent to those described above.

For example, when the motherboard 13b is carried, or when the motherboard 13b is assembled into the information processing apparatus 11, if an external force acts on the printed wiring board 14, a stress may be generated in the printed wiring board 14. The spacer 35 contacts the back surface of the printed wiring board 14 by a large contact area. Consequently, the stress can be further properly dispersed in the printed wiring board 14. Accordingly, cracking of the printed wiring board 14, and breaking of the wiring pattern in the printed wiring board 14 can be prevented. In addition, since merely the through holes 36 are formed in the spacer 35, the position accuracy requirement of the through holes 36 may be lower than the position accuracy when screw holes are formed in a bolster plate of related art. Consequently, the spacer 35 can be reduced in manufacturing cost as compared with the bolster plate of related art. In addition, as long as the through holes 36 have a relatively large diameter, the spacer 35 can be reduced in weight as compared with the bolster plate of related art. The motherboard 13b can be reduced in its total weight.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

1. A printed circuit board unit, comprising:
a printed wiring board;
an electronic component package mounted on a first surface of the printed wiring board;
a radiating plate that is placed on an upper surface of the electronic component package;
at least one bolt having a head and a tip protruding from a second surface of the printed wiring board opposite of the first surface, and penetrates through the radiating plate and the printed wiring board;
a reinforcing plate separated from the second surface of the printed wiring board by a predetermined gap;
at least one stud arranged on a first surface of the reinforcing plate and coupled with the tip of the at least one bolt; and
at least one shock absorbing plate that is arranged between the reinforcing plate and the second surface of the printed wiring board.

2. The printed circuit board unit according to claim 1, wherein the at least one shock absorbing plate is coupled with the reinforcing plate.

3. The printed circuit board unit according to claim 1, wherein the at least one shock absorbing plate is integrated with the reinforcing plate and is formed by a bent portion of the reinforcing plate.

4. A printed circuit board unit, comprising:
a printed wiring board;
an electronic component package mounted on a first surface of the printed wiring board;
a radiating plate that is placed on an upper surface of the electronic component package;
at least one bolt having a head and a tip protruding from a second surface of the printed wiring board opposite of the first surface, and penetrates through the radiating plate and the printed wiring board;
a reinforcing plate separated from the second surface of the printed wiring board by a predetermined gap;
at least one stud arranged on a first surface of the reinforcing plate and coupled with the tip of the at least one bolt; and
at least one spacer that is arranged between the second surface of the printed wiring board and the first surface of the reinforcing plate, and has a through hole configured to receive the at least one stud.

5. The printed circuit board unit according to claim 4, wherein a height of the at least one stud from the first surface of the reinforcing plate is smaller than a thickness of the at least one spacer.

6. An electric apparatus including a printed circuit board unit in a casing, the printed circuit board unit comprising:
a printed wiring board;
an electronic component package mounted on a first surface of the printed wiring board;
a radiating plate that is placed on an upper surface of the electronic component package;
at least one bolt having a head and a tip protruding from a second surface of the printed wiring board opposite of the first surface, and penetrates through the radiating plate and the printed wiring board;
a reinforcing plate separated from the second surface of the printed wiring board by a predetermined gap;
at least one stud arranged on a first surface of the reinforcing plate and coupled with the tip of the at least one bolt; and
at least one shock absorbing plate that is arranged between the reinforcing plate and the second surface of the printed wiring board.

7. The electric apparatus according to claim 1, wherein the at least one shock absorbing plate is coupled with the reinforcing plate.

8. The electric apparatus according to claim 1, wherein the at least one shock absorbing plate is integrated with the reinforcing plate and is formed by a bent portion of the reinforcing plate.
